(19) United States
(12) Patent Application Publication
(10) Pub. No.: US 2014/0091424 A1
(43) Pub. Date: Apr. 3, 2014

(54) COMPOUND SEMICONDUCTOR DEVICE AND MANUFACTURING METHOD THEREOF

(71) Applicant: FUJITSU LIMITED, Kawasaki-shi (JP)

(72) Inventor: Kozo MAKIYAMA, Kawasaki (JP)

(21) Appl. No.: 13/943,427

(22) Filed: Jul. 16, 2013

(30) Foreign Application Priority Data
Sep. 28, 2012 (JP) 2012-217691

(51) Int. Cl. H01L 29/778; H01L 29/66

(52) U.S. Cl. CPC H01L 29/778; H01L 29/66431
USPC 257/472; 438/478

(57) ABSTRACT

A compound semiconductor device includes: a compound semiconductor layer; a protective insulating film that covers a top of the compound semiconductor layer and has an opening formed thereon; and an electrode that fills the opening, that is brought into contact with the compound semiconductor layer, and that is formed on the protective insulating film, in which an orientation state of a contact portion between the electrode and the compound semiconductor layer and an orientation state of a contact portion between the electrode and the protective insulating film are the same.

### CROSS-REFERENCE TO RELATED APPLICATION

This application is based upon and claims the benefit of priority of the prior Japanese Patent Application No. 2012-217691, filed on Sep. 28, 2012, the entire contents of which are incorporated herein by reference.

### FIELD

The embodiments discussed herein are directed to a compound semiconductor device and a manufacturing method thereof.

### BACKGROUND

Compound semiconductor devices, in particular, nitride semiconductor devices have been actively developed as high-withstand-voltage and high-power semiconductor devices, by utilizing their characteristics such as a high saturation electron velocity, a wide band gap, and so on. Many reports have been made on field-effect transistors, in particular, HEMTs (High Electron Mobility Transistors) as the nitride semiconductor devices. Especially, an AlGaN/GaN HEMT using GaN as an electron transit layer and using AlGaN as an electron supply layer has been drawing attention. In the AlGaN/GaN HEMT, a distortion resulting from a difference in lattice constants between GaN and AlGaN occurs in AlGaN.

Owing to piezoelectric polarization caused by the distortion and spontaneous polarization of AlGaN, high-concentration two-dimensional electron gas (2DEG) is obtained. This makes it possible to realize high withstand voltage and high output power.
Patent Document 1: Japanese Laid-open Patent Publication No. 2011-238805
Patent Document 2: Japanese Laid-open Patent Publication No. 2010-21197
Patent Document 3: Japanese Laid-open Patent Publication No. 2010-118556

Regarding the HEMT, research and development are advanced for a gate electrode which can reduce a gate capacitance and a gate resistance in order to further improve high-frequency characteristics. There is devised an HEMT having a gate electrode whose cross section along a gate length has a so-called overhang shape, and is composed of a narrow fine gate and a wide over gate thereon, which are integrally formed. The gate electrode of the HEMT is formed of a plurality of layers of metals, in order to achieve both of Schottky property and low resistance. Generally, Ni is often used as a Schottky metal, and Au is often used as a low-resistance metal. In the gate electrode in the overhang shape, on a nitride semiconductor, a protective film having an opening that exposes a part of the nitride semiconductor is formed, in which Ni is in Schottky contact with the nitride semiconductor and is formed on the protective film, and Au is stacked on Ni. In this case, due to a difference in properties between a surface of the protective film and a surface of the nitride semiconductor exposed from the opening, an orientation of Ni on the protective film and an orientation of Ni on the nitride semiconductor become different. A boundary portion of the mutually different orientations becomes a path through which Au on Ni is diffused on the compound semiconductor side. Due to this diffusion phenomenon, the diffused Au conclusively reacts with the compound semiconductor, which causes a breakdown of device.

### SUMMARY

An aspect of a compound semiconductor device includes: a compound semiconductor layer; a protective insulating film that covers a top of the compound semiconductor layer and has an opening formed thereon; and an electrode that fills the opening, that is brought into contact with the compound semiconductor layer, and that is formed on the protective insulating film, in which an orientation state of a contact portion between the electrode and the compound semiconductor layer and an orientation state of a contact portion between the electrode and the protective insulating film are the same.

An aspect of a manufacturing method of a compound semiconductor device includes: forming a compound semiconductor layer; forming a protective insulating film that covers a top of the compound semiconductor layer and has an opening; and forming an electrode that fills the opening, that is brought into contact with the compound semiconductor layer, and that exists on the protective insulating film, in which an orientation state of a contact portion between the electrode and the compound semiconductor layer and an orientation state of a contact portion between the electrode and the protective insulating film are set to be the same.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A to FIG. 1C are schematic cross-sectional diagrams illustrating a manufacturing method of an AlGaN/GaN HEMT according to a first embodiment in order of processes;

FIG. 2A to FIG. 2C are schematic cross-sectional diagrams illustrating the manufacturing method of the AlGaN/GaN HEMT according to the first embodiment in order of processes, continued from FIG. 1C;

FIG. 3A and FIG. 3B are schematic cross-sectional diagrams illustrating the manufacturing method of the AlGaN/GaN HEMT according to the first embodiment in order of processes, continued from FIG. 2C;

FIG. 4 is a schematic cross-sectional diagram illustrating a conventional AlGaN/GaN HEMT as a comparative example;

FIG. 5A to FIG. 5C are characteristic charts for explaining advantages of forming a protective insulating film with high N—H concentration according to the first embodiment;

FIG. 6 is a characteristic chart presenting results of a high-temperature current conduction test carried out on the AlGaN/GaN HEMT according to the first embodiment, based on comparison with the comparative example;

FIG. 7A to FIG. 7C are schematic cross-sectional diagrams illustrating main processes in a manufacturing method of an AlGaN/GaN HEMT according to a second embodiment;

FIG. 8 is a characteristic chart presenting results of a high-temperature current conduction test carried out on the AlGaN/GaN HEMT according to the second embodiment, based on comparison with the comparative example;

FIG. 9A to FIG. 9C are schematic cross-sectional diagrams illustrating main processes in a manufacturing method of an AlGaN/GaN HEMT according to a third embodiment;

FIG. 10 is a partial cross-sectional diagram illustrating a part within a circle C in FIG. 9B, in an enlarged manner;

FIG. 11 is a characteristic chart presenting results of a high-temperature current conduction test carried out on the AlGaN/GaN HEMT according to the third embodiment, based on comparison with the comparative example;

FIG. 12 is a connection diagram illustrating a schematic configuration of a power supply device according to a fourth embodiment; and

FIG. 13 is a connection diagram illustrating a schematic configuration of a high-frequency amplifier according to a fifth embodiment.

### DESCRIPTION OF EMBODIMENTS

Hereinafter, embodiments will be described in detail with reference to the drawings. In the following embodiments, a configuration of a compound semiconductor device will be described along with a manufacturing method of the compound semiconductor device.

Note that in the following drawings, some constituent members are not illustrated with relatively accurate size and thickness for convenience of illustration.

### First Embodiment

In the present embodiment, a Schottky-type AlGaN/GaN HEMT is disclosed as a compound semiconductor device.

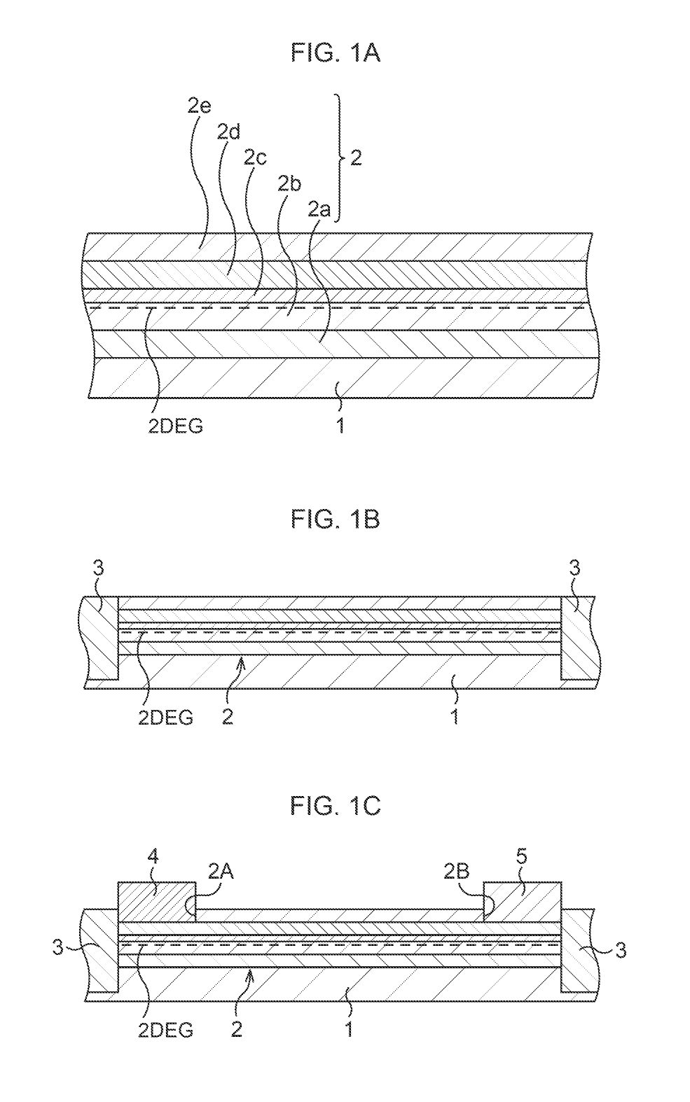

FIG. 1A to FIG. 1C to FIG. 3A to FIG. 3C are schematic cross-sectional diagrams illustrating a manufacturing method of the Schottky-type AlGaN/GaN HEMT according to the first embodiment in order of processes.

First, as illustrated in FIG. 1A, a compound semiconductor layer 2 having a stacked structure of compound semiconductors is formed on, for example, a semi-insulating SiC substrate 1 being a growth substrate.

As the growth substrate, a Si substrate, a sapphire substrate, a GaAs substrate, a GaN substrate, or the like may be used instead of the SiC substrate. Further, a conductivity of the substrate may be either semi-insulating or conductive.

The compound semiconductor layer 2 is configured to have a buffer layer 2a, an electron transit layer 2b, an intermediate layer 2c, an electron supply layer 2d, and a cap layer 2e. In the AlGaN/GaN HEMT, two-dimensional electron gas (2DEG) is generated in the vicinity of an interface of the electron transit layer 2b with the electron supply layer 2d (to be exact, the intermediate layer 2c).

Specifically, on the SiC substrate 1, the following respective compound semiconductors are grown by, for example, an MOVPE (Metal Organic Vapor Phase Epitaxy) method. An MBE (Molecular Beam Epitaxy) method or the like may also be used instead of the MOVPE method.

On the SiC substrate 1, AlN, i(intentionally undoped)-GaN, i-AlGaN, n-AlGaN and n-GaN are sequentially deposited to stack and form the buffer layer 2a, the electron transit layer 2b, the intermediate layer 2c, the electron supply layer 2d, and the cap layer 2e. As a growth condition of AlN, GaN, AlGaN, and GaN, a mixed gas of trimethylaluminum gas, trimethylgallium gas, and ammonia gas is used as a source gas. Depending on the compound semiconductor layer to be grown, the presence/absence of supply of the trimethylaluminum gas being an Al source and the trimethylgallium gas being a Ga source and their flow rates are appropriately set. A flow rate of the ammonia gas being a common source is set to about 100 sccm to about 10 LM. Further, a growth pressure is set to about 50 Torr to about 300 Torr, and a growth temperature is set to about 1000° C. to about 1200° C.

To grow GaN and AlGaN as an n-type, namely, to grow n-GaN of the cap layer 2e and n-AlGaN of the electron supply layer 2d, for example, SiH₄ gas containing Si as n-type impurity, for example, is added to the source gas at a predetermined flow rate. Accordingly, Si is doped into GaN and AlGaN. A doping concentration of Si is set to about 1×10¹⁸/cm³ to about 5×10¹⁸/cm³, for example, about 5×10¹⁸/cm³.

Here, the buffer layer 2a is formed with a thickness of about 0.1 μm, the electron transit layer 2b is formed with a thickness of about 3 μm, the intermediate layer 2c is formed with a thickness of about 5 nm, the electron supply layer 2d is formed with a thickness of about 20 nm and an Al ratio of about 0.2 to about 0.3, for example, and the cap layer 2e is formed with a thickness of about 10 nm.

Subsequently, element isolation structures 3 are formed as illustrated in FIG. 1B.

Specifically, argon (Ar), for instance, is injected to element isolation regions of the compound semiconductor layer 2. Accordingly, the element isolation structures 3 are formed in the compound semiconductor layer 2 and in a surface layer portion of the SiC substrate 1. The element isolation structures 3 demarcate an active region on the compound semiconductor layer 2.

Note that the element isolation may also be performed by using an STI (Shallow Trench Isolation) method, for example, instead of the above-described injection method.

Subsequently, as illustrated in FIG. 1C, a source electrode 4 and a drain electrode 5 are formed.

Specifically, electrode trenches 2A and 2B are first formed in the cap layer 2e at formation scheduled positions for a source electrode and a drain electrode in a surface of the compound semiconductor layer 2.

A resist mask having openings at the formation scheduled positions for the source electrode and the drain electrode in the surface of the compound semiconductor layer 2, is formed. By using this resist mask, the cap layer 2e is dry-etched to be removed. Accordingly, the electrode trenches 2A and 2B are formed. For the dry etching, an inert gas of Ar or the like and chlorine gas of Cl₂ or the like are used as an etching gas. Here, the electrode trenches may also be formed by performing dry etching to penetrate through the cap layer 2e down to a surface layer portion of the electron supply layer 2d.

As an electrode material, Ti/Al is used, for instance. To form the electrodes, an eaves-structure two-layer resist, for example, suitable for a vapor deposition method and a liftoff method is used. This resist is applied on the compound semiconductor layer 2 to form a resist mask having openings at the electrode trenches 2A and 2B. Ti/Al is deposited by using this resist mask. A thickness of Ti is set to about 20 nm, and a thickness of Al is set to about 200 nm. By the liftoff method, the resist mask with the eaves structure and Ti/Al deposited thereon are removed. Thereafter, the SiC substrate 1 is heat-treated at about 550° C. in a nitrogen atmosphere, for example, and the remaining Ti/Al is brought into ohmic contact with the electron supply layer 2d. Through the above processes, the source electrode 4 and the drain electrode 5 having the electrode trenches 2A and 2B embedded under Ti/Al, are formed.

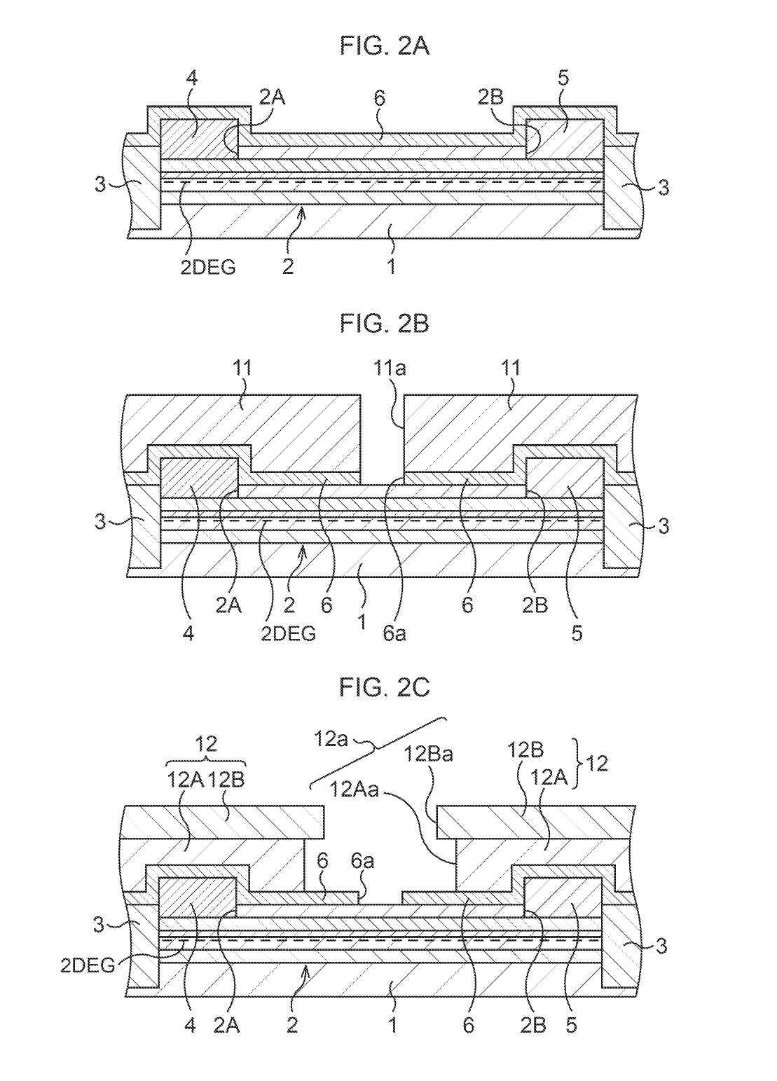

Subsequently, as illustrated in FIG. 2A, a protective insulating film 6 is formed.

Specifically, an insulator, for example, silicon nitride (SiN) is deposited on the whole surface of the compound semiconductor layer 2 to, for example, a thickness of about 50 nm by using a plasma CVD method or the like. Accordingly, the protective insulating film 6 is formed. The protective insulating film 6 contains, in at least a surface layer thereof (in the entire film, in the present embodiment), N—H bonds whose number exceeds 1×10²²/cm³. In order to form the silicon nitride film, for example, silane (SiH₄) is used as a Si raw material, ammonia (NH₃) is used as an N raw material, and an RF power for turning the material gas into plasma is set to about 50 W, to thereby create a state in which NH₃ is completely excited, namely, no hydrogen is separated. Note that in order to make an N/Si ratio in the protective insulating film 6 to be close to stoichiometry of 4/3, a flow rate of SiH₄ is set to 2.5 sccm, and a flow rate of NH₃ is set to 2 sccm, as a deposition condition. The protective insulating film 6 formed by the deposition condition contains N—H bonds whose number is about 2×10²²/cm³, and has a refractive index with respect to light with a wavelength of 633 nm of more than 1.9 and equal to or less than 2.0, for example, 1.91. A surface oxidation of the protective insulating film 6 is reduced to about one-fifth (integral value of SIMS profile) of that of a typical stoichiometric silicon nitride film.

Subsequently, as illustrated in FIG. 2B, a trench 6a is formed in the protective insulating film 6.

Specifically, a resist is first applied on the whole surface of the protective insulating film 6. For example, PFI-32 (trade name) manufactured by Sumitomo Chemical Co., Ltd. is used as the resist. An ultraviolet method is used to perform, for example, exposure for an opening having a width of 600 nm on the applied resist, and the resist is developed. For example, NMD-W (trade name) manufactured by Tokyo Ohka Kogyo Co., Ltd. is used as a developing solution. Accordingly, a resist mask 11 having an opening 11a is formed.

Next, dry etching using the resist mask 11 is performed on the protective insulating film 6 until when a surface of the cap layer 2e is exposed at the bottom of the opening 11a. For example, SF₆ is used as an etching gas. Accordingly, the trench 6a that is a through trench having a width of about 600 nm and exposing the surface of the cap layer 2e, is formed in the protective insulating film 6. The trench 6a is formed at a formation scheduled site for a fine gate of a gate electrode to be formed at subsequent processes in the protective insulating film 6.

The resist mask 11 is removed by ashing using oxygen plasma or wet treatment using a chemical solution.

Subsequently, as illustrated in FIG. 2C, a resist mask 12 for forming a gate is formed.

Specifically, each of a lower-layer resist 12A (for example, PMGI (trade name): manufactured by Micro-Chem Inc. in the United States) and an upper-layer resist 12B (for example, PFI-32 (trade name): manufactured by Sumitomo Chemical Co., Ltd.) is first applied on the whole surface by a spin coating method, for example. Ultraviolet exposure is performed to form an opening 12Ba having a diameter of about 1.5 μm, for example, in the upper-layer resist 12B. Next, wet etching using an alkali developing solution is performed on the lower-layer resist 12A by using the upper-layer resist 12B as a mask, to thereby form an opening 12Aa in the lower-layer resist 12A. Through the above processes, the resist mask 12 formed of the lower-layer resist 12A having the opening 12Aa and the upper-layer resist 12B having the opening 12Ba, is formed. In the resist mask 12, an opening where the opening 12Aa and the opening 12Ba communicate with each other is denoted by 12a.

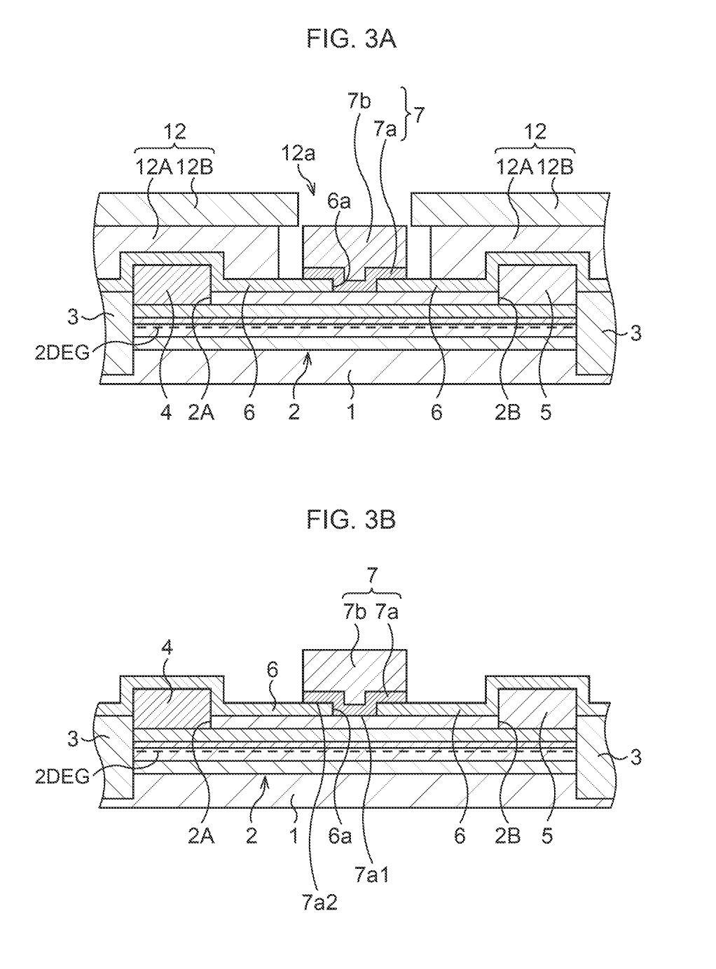

Subsequently, as illustrated in FIG. 3A, a gate electrode 7 is formed.

Specifically, as gate metals, Ni is deposited to have a thickness of about 10 nm, and followed by the deposition, Au is deposited to have a thickness of about 300 nm, on the whole surface including the inside of the opening 12a using the resist mask 12. The illustration of gate metals deposited on the resist mask 12 is omitted. Through the above processes, the gate electrode 7 in which a Ni layer 7a and an Au layer 7b are stacked, is formed.

Note that regarding the gate electrode 7, it is also possible that a conductive layer (conductive nitride or the like) for improving the barrier property is interposed between the Ni7a and the Au7b.

Subsequently, as illustrated in FIG. 3B, the resist mask 12 is removed.

Specifically, the SiC substrate 1 is immersed in N-methyl-pyrrolidinone warmed at 80° C., and the resist mask 12 and unnecessary gate metals are removed by the liftoff method.

The gate electrode 7 has a so-called overhang shape, and is formed by having the Ni layer 7a which fills the trench 6a of the protective insulating film 6, which is in Schottky contact with the compound semiconductor layer 2 (cap layer 2e), and which rides on the protective insulating film 6, and the Au layer 7b on the Ni layer 7a. In the Ni layer 7a, a portion which is in Schottky contact with the compound semiconductor layer 2 (cap layer 2e) is set to a first contact portion 7a1, and a portion, on the protective insulating film 6, that is brought into contact with the protective insulating film 6 is set to a second contact portion 7a2. In the present embodiment, the protective insulating film 6 contains N—H bonds whose number exceeds 1×10²²/cm³, and is formed of SiN which is not oxidized. For this reason, an orientation state of the second contact portion 7a2 that is brought into contact with the protective insulating film 6 is set to the same orientation state as that of the first contact portion 7a1 which is in Schottky contact with the compound semiconductor layer 2 (cap layer 2e). Note that regarding the gate electrode 7, by interposing the conductive layer for improving the barrier property between the Ni7a and the Au7b, it is possible to further improve the metal diffusion resistance.

Thereafter, through processes of electrical connection of the source electrode 4, the drain electrode 5, and the gate electrode 7 and the like, the Schottky-type AlGaN/GaN HEMT is formed.

Hereinafter, operations and effects achieved by the AlGaN/GaN HEMT according to the present embodiment will be described, based on comparison with a comparative example.

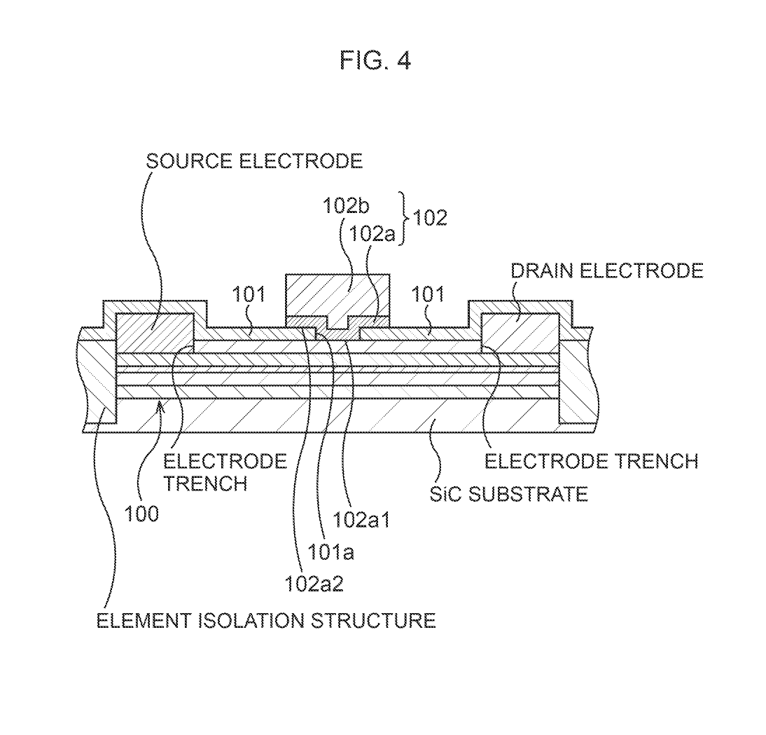

FIG. 4 is a schematic cross-sectional diagram illustrating a conventional AlGaN/GaN HEMT as the comparative example of the present embodiment.

As illustrated in FIG. 4, in the Schottky-type AlGaN/GaN HEMT according to the comparative example, a protective insulating film 101 is formed instead of the protective insulating film 6, and a gate electrode 102 is formed instead of the gate electrode 7 in FIG. 3B. The protective insulating film 101 contains N—H bonds whose number is about (5×10²¹/cm³), for example, and is formed of stoichiometric SiN with a thickness of about 50 nm, for example. In the protective insulating film 101, an opening 101a being a through trench is formed. The gate electrode 102 is formed in an overhang shape with a stacked structure of a Ni layer 102a which fills the opening 101a, which is in Schottky contact with a surface of a compound semiconductor layer 100, and which rides on the protective insulating film 101, and an Au layer 102b on the Ni layer 102a. In the Ni layer 102a, a portion which is in Schottky contact with the compound semiconductor layer 100 is set to a first contact portion 102a1, and a portion, on the protective insulating film 101, that is brought into contact with the protective insulating film 101 is set to a second contact portion 102a2. Further, for example, a source field plate having the same electric potential as that of the source electrode is formed, and an end of the source field plate is disposed above an appropriate position between the gate electrode and the drain electrode.

In the AlGaN/GaN HEMT of the comparative example, an orientation state of the second contact portion 102a2, in the Ni layer 102a, which is brought into contact with the protective insulating film 101 and an orientation state of the first contact portion 102a1, in the Ni layer 102a, which is in Schottky contact with the compound semiconductor layer 100, are different. A boundary portion of the mutually different orientations becomes a path through which Au is diffused on the compound semiconductor side from the Au layer 102b on the Ni layer 102a. Due to this diffusion phenomenon, the diffused Au conclusively reacts with the compound semiconductor, which causes a breakdown of device. Note that it is possible to interpose a metal layer for securing the barrier property also in the gate electrode 102 between the Ni layer 102a and the Au layer 102b, but, due to the boundary of orientation, it is not possible to sufficiently suppress the diffusion from the Au layer 102b.

In the present embodiment, as illustrated in FIG. 3B, for example, the protective insulating film 6 with high hydrogen content in which it contains N—H bonds whose number exceeds 1×10²²/cm³, is formed. Hydrogen in the protective insulating film 6 improves the water repellency on the surface of the protective insulating film 6, and prevents the surface oxidation.

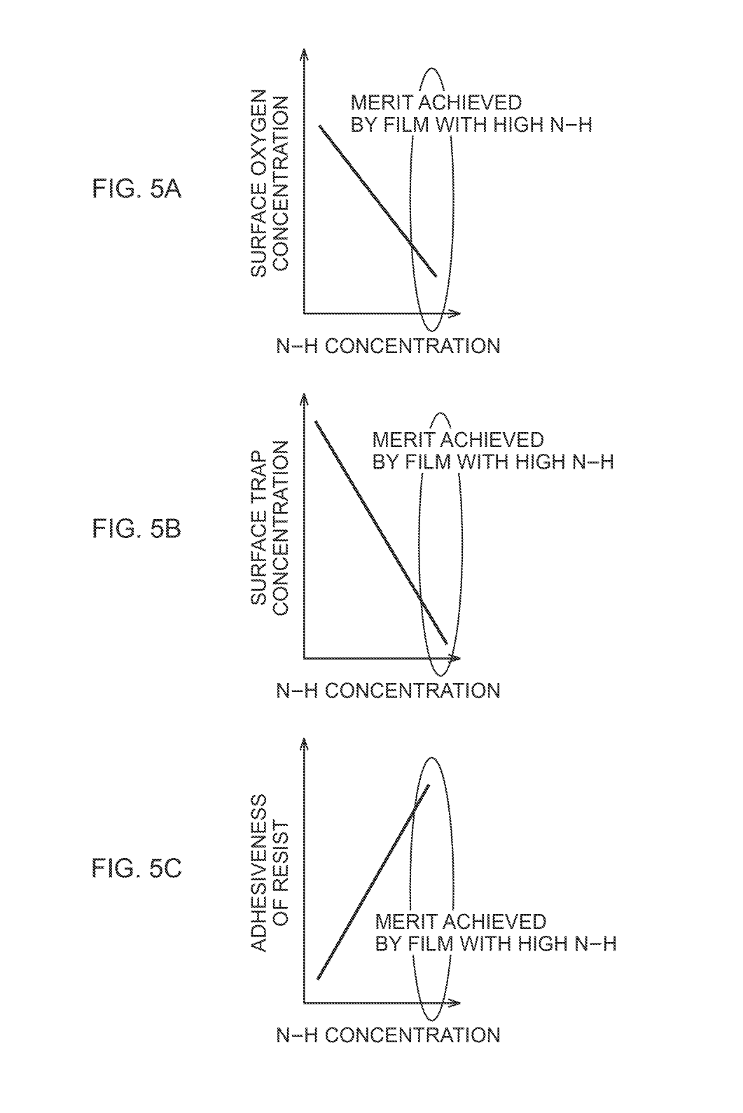

Advantages of using the silicon nitride film containing a large amount of hydrogen bonded to nitrogen, as the protective insulating film, will be described by using FIG. 5A to FIG. 5C. FIG. 5A to FIG. 5C are characteristic charts illustrating characteristics which are dependent on a content of N—H bonds in a deposited silicon nitride film.

As illustrated in FIG. 5A, as the content of N—H bonds of the silicon nitride film is increased, a surface oxygen concentration of the silicon nitride film is lowered. As illustrated in FIG. 5B, as the content of N—H bonds of the silicon nitride film is increased, a surface trap concentration of the silicon nitride film is lowered. As illustrated in FIG. 5C, as the content of N—H bonds of the silicon nitride film is increased, an adhesiveness of resist with respect to the top of the silicon nitride film is improved.

In the present embodiment, the surface oxygen concentration and the surface trap concentration of the protective insulating film 6 are quite low, compared to those of the protective insulating film 101 in the comparative example. For this reason, in the Ni layer 7a of the gate electrode 7, a change in the orientations of the second contact portion 7a2 which is brought into contact with the protective insulating film 6 and the first contact portion 7a1 which is in Schottky contact with the compound semiconductor layer 2 (cap layer 2e) is suppressed, resulting in that the both contact portions have a uniform orientation state. Accordingly, the path through which Au is diffused from the Au layer 7b is not formed, resulting in that the diffusion of Au is suppressed, and the breakdown of device is prevented.

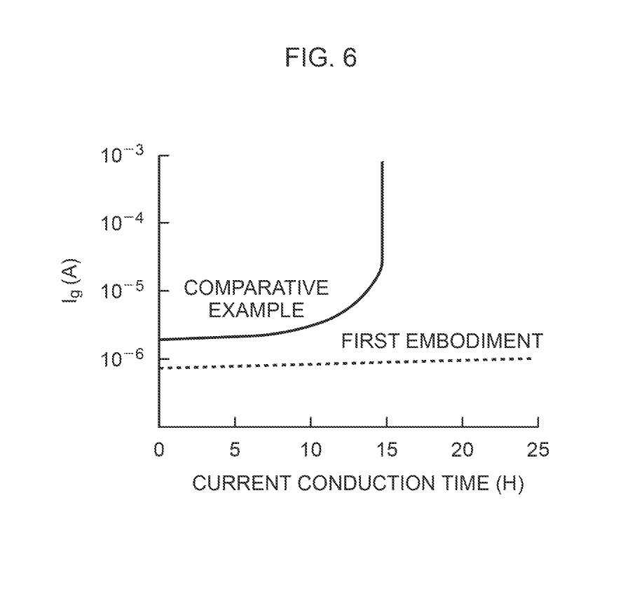

Further, a high-temperature current conduction test was carried out on the AlGaN/GaN HEMT according to the present embodiment, based on comparison with the above-described comparative example. The results are presented in FIG. 6.

It was confirmed that, in the present embodiment, the change in gate current (gate leakage current) in the high-temperature current conduction test was small and no breakdown occurred, unlike the comparative example. Namely, application of the protective insulating film 6 in the present embodiment realizes a highly reliable AlGaN/GaN HEMT with excellent output characteristics.

As described above, according to the present embodiment, it is possible to obtain a highly reliable AlGaN/GaN HEMT which suppresses a diffusion of gate electrode material and suppresses a breakdown of device by a relatively simple configuration to achieve high withstand voltage and high output power.

### Second Embodiment

Hereinafter, an AlGaN/GaN HEMT according to a second embodiment will be described. The present embodiment is different from the first embodiment in that a configuration of protective insulating film in the AlGaN/GaN HEMT in the second embodiment is slightly different from that of the first embodiment. Note that constituent members and the like similar to those of the AlGaN/GaN HEMT according to the first embodiment will be denoted by the same reference numerals, and detailed explanation thereof will be omitted.

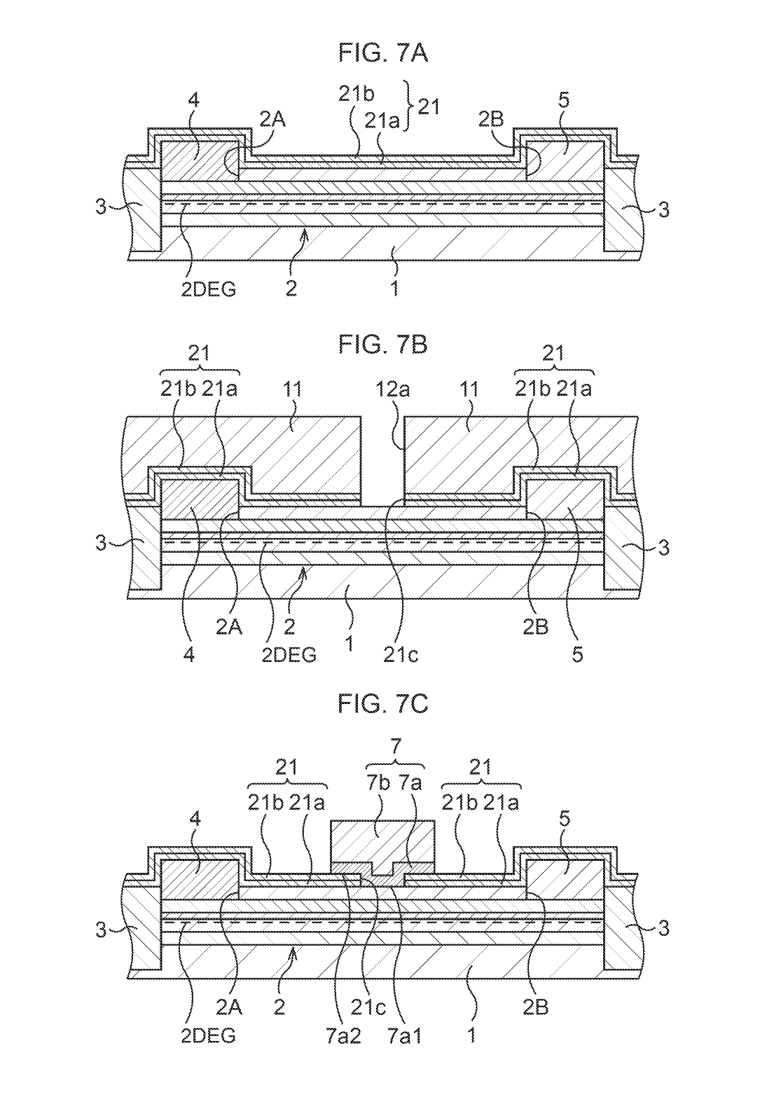

FIG. 7A to FIG. 7C are schematic cross-sectional diagrams illustrating main processes in a manufacturing method of the AlGaN/GaN HEMT according to the second embodiment.

First, through the processes in FIG. 1A to FIG. 1C of the first embodiment, a source electrode 4 and a drain electrode 5 are formed on a compound semiconductor layer 2.

Subsequently, a protective insulating film 21 is formed, as illustrated in FIG. 7A.

Specifically, an insulator, for example, silicon nitride (SiN) is deposited on the whole surface of the compound semiconductor layer 2 using a plasma CVD method or the like, to thereby sequentially deposit a first insulating film 21a and a second insulating film 21b. Accordingly, the protective insulating film 21 having a stacked structure of the first insulating film 21a and the second insulating film 21b, is formed.

The first insulating film 21a is deposited to have a thickness of about 40 nm, for example, under an arbitrary deposition condition, which is, in this case, a condition in which a silicon nitride film suitable for protecting (passivating) a surface of the compound semiconductor layer 2 is formed. As the deposition condition in which the silicon nitride film suitable for passivating the compound semiconductor layer 2 described above is formed, it is appropriate to adopt a deposition condition for stoichiometric film, such that a flow rate of SiH₄ is set to 2.5 sccm, a flow rate of N₂ is set to 300 sccm, and an RF power is set to 80 W, for example.

The second insulating film 21b is deposited to have a thickness of about 10 nm, for example, and contains, in at least a surface layer thereof (in the entire film, in the present embodiment), N—H bonds whose number exceeds 1×10²²/cm³. In order to form the silicon nitride film, for example, silane (SiH₄) is used as a Si raw material, ammonia (NH₃) is used as an N raw material, and an RF power for turning the material gas into plasma is set to about 50 W, to thereby create a state in which NH₃ is completely excited, namely, no hydrogen is separated. Note that in order to make an N/Si ratio in the second insulating film 21b to be close to stoichiometry of 4/3, a flow rate of SiH₄ is set to 2.5 sccm, and a flow rate of NH₃ is set to 2 sccm, as a deposition condition. The second insulating film 21b formed by the deposition condition contains N—H bonds whose number is about 2×10²²/cm³, and has a refractive index with respect to light with a wavelength of 633 nm of more than 1.9 and equal to or less than 2.0, for example, 1.91. A surface oxidation of the second insulating film 21b is reduced to about one-fifth (integral value of SIMS profile) of that of a typical stoichiometric silicon nitride film.

Subsequently, as illustrated in FIG. 7B, a trench 21c is formed in the protective insulating film 21.

Specifically, a resist is first applied on the whole surface of the protective insulating film 21. For example, PFI-32 (trade name) manufactured by Sumitomo Chemical Co., Ltd. is used as the resist. An ultraviolet method is used to perform, for example, exposure for an opening having a width of 600 nm on the applied resist, and the resist is developed. For example, NMD-W (trade name) manufactured by Tokyo Ohka Kogyo Co., Ltd. is used as a developing solution. Accordingly, a resist mask 11 having an opening 12a is formed.

Next, dry etching using the resist mask 11 is performed on the protective insulating film 21 until when a surface of a cap layer 2e is exposed at the bottom of the opening 12a. For example, SF₆ is used as an etching gas. Accordingly, the trench 21c that is a through trench having a width of about 600 nm and exposing the surface of the cap layer 2e, is formed in the protective insulating film 21. The trench 21c is formed at a formation scheduled site for a fine gate of a gate electrode to be formed at subsequent processes in the protective insulating film 21.

The resist mask 12 is removed by ashing using oxygen plasma or wet treatment using a chemical solution.

Subsequently, a gate electrode 7 is formed as illustrated in FIG. 7C, in a manner similar to that of FIG. 2C to FIG. 3B of the first embodiment.

Similar to the first embodiment, the gate electrode 7 in which a Ni layer 7a and an Au layer 7b are stacked, is formed. The gate electrode 7 has a so-called overhang shape, and is formed by having the Ni layer 7a which fills the trench 21c of the protective insulating film 21, which is in Schottky contact with the compound semiconductor layer 2 (cap layer 2e), and which rides on the protective insulating film 21, and the Au layer 7b on the Ni layer 7a. In the Ni layer 7a, a portion which is in Schottky contact with the compound semiconductor layer 2 (cap layer 2e) is set to a first contact portion 7a1, and a portion that is brought into contact with the second insulating film 21b of the protective insulating film 21 is set to a second contact portion 7a2. In the present embodiment, the second insulating film 21b contains N—H bonds whose number exceeds 1×10²²/cm³, and is formed of SiN which is not oxidized. For this reason, an orientation state of the second contact portion 7a2 that is brought into contact with the second insulating film 21b is set to the same orientation state as that of the first contact portion 7a1 which is in Schottky contact with the compound semiconductor layer 2 (cap layer 2e). Note that regarding the gate electrode 7, by interposing a conductive layer for improving the barrier property between the Ni layer 7a and the Au layer 7b, it is possible to further improve the metal diffusion resistance.

Thereafter, through processes of electrical connection of the source electrode 4, the drain electrode 5, and the gate electrode 7 and the like, the Schottky-type AlGaN/GaN HEMT is formed.

In the present embodiment, the protective insulating film 21 is formed of the stacked structure of the first insulating film 21a and the second insulating film 21b, as illustrated in FIG. 7C, for example. The protective insulating film 21 has not only the property of suppressing the oxidation on the surface thereof, which causes a change in the orientation state of Ni of the Ni layer 7a of the gate electrode 7, but also the optimum property for passivating the surface of the compound semiconductor layer 2.

In the protective insulating film 21, the second insulating film 21b being the upper layer is formed as the insulating film with high hydrogen content in which it contains N—H bonds whose number exceeds 1×10²²/cm³. Hydrogen in the second insulating film 21b improves the water repellency on the surface of the second insulating film 21b, and prevents the surface oxidation. In the present embodiment, the surface oxygen concentration and the surface trap concentration of the second insulating film 21b are quite low. For this reason, in the Ni layer 7a of the gate electrode 7, a change in the orientations of the second contact portion 7a2 which is brought into contact with the second insulating film 21b and the first contact portion 7a1 which is in Schottky contact with the compound semiconductor layer 2 (cap layer 2e) is suppressed, resulting in that the both contact portions have a uniform orientation state. Accordingly, the path through which Au is diffused from the Au layer 7b is not formed, resulting in that the diffusion of Au is suppressed, and the breakdown of device is prevented.

An insulating film containing a large amount of hydrogen lacks in density, and due to imperfection of bonding, there is a worry that a trap in the insulating film is increased. In that case, there is a possibility that the insulating film with high hydrogen content in which it contains N—H bonds whose number exceeds 1×10²²/cm³ is excellent as the insulating film which is brought into contact with the Ni layer of the gate electrode, but, it is not so excellent as the protective film of the compound semiconductor layer.

Accordingly, in the present embodiment, the first insulating film 21a being the lower layer of the protective insulating film 21 is formed of the silicon nitride film suitable for protecting (passivating) the surface of the compound semiconductor layer 2.

In the present embodiment, the protective insulating film 21 is formed to have the stacked structure of the first insulating film 21a and the second insulating film 21b. By this configuration, the first insulating film 21a securely protects the surface of the compound semiconductor layer 2 to suppress a change in characteristics caused by an electron trap typified by a current collapse or the like, and the second insulating film 21b securely suppresses the diffusion of Au from the Au layer 7b of the gate electrode 7.

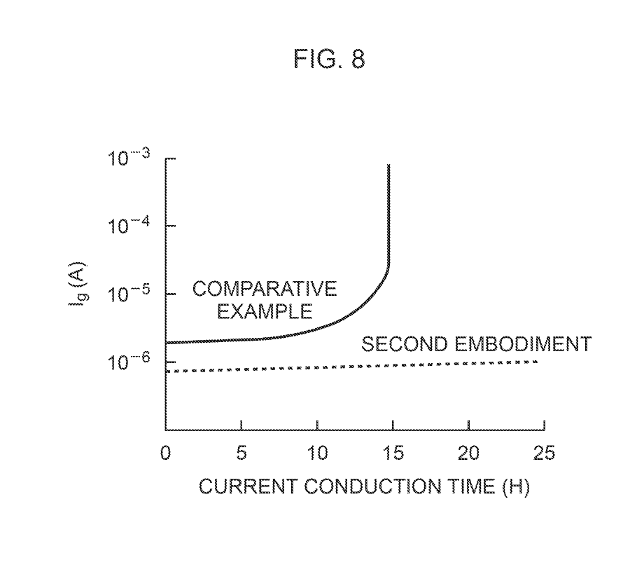

A high-temperature current conduction test was carried out on the AlGaN/GaN HEMT according to the present embodiment, based on comparison with the comparative example cited in FIG. 4 of the first embodiment. The results are presented in FIG. 8.

It was confirmed that, in the present embodiment, the change in gate current (gate leakage current) in the high-temperature current conduction test was small and no breakdown occurred, unlike the comparative example. Namely, application of the protective insulating film 21 in the present embodiment realizes a highly reliable AlGaN/GaN HEMT with excellent output characteristics.

As described above, according to the present embodiment, it is possible to obtain a highly reliable AlGaN/GaN HEMT which suppresses a diffusion of gate electrode material and suppresses a breakdown of device by a relatively simple configuration to achieve high withstand voltage and high output power.

### Third Embodiment

Hereinafter, an AlGaN/GaN HEMT according to a third embodiment will be described. The present embodiment is different from the first embodiment in that a shape of opening of a protective insulating film in the AlGaN/GaN HEMT in the third embodiment is slightly different from that of the first embodiment. Note that constituent members and the like similar to those of the AlGaN/GaN HEMT according to the first embodiment will be denoted by the same reference numerals, and detailed explanation thereof will be omitted.

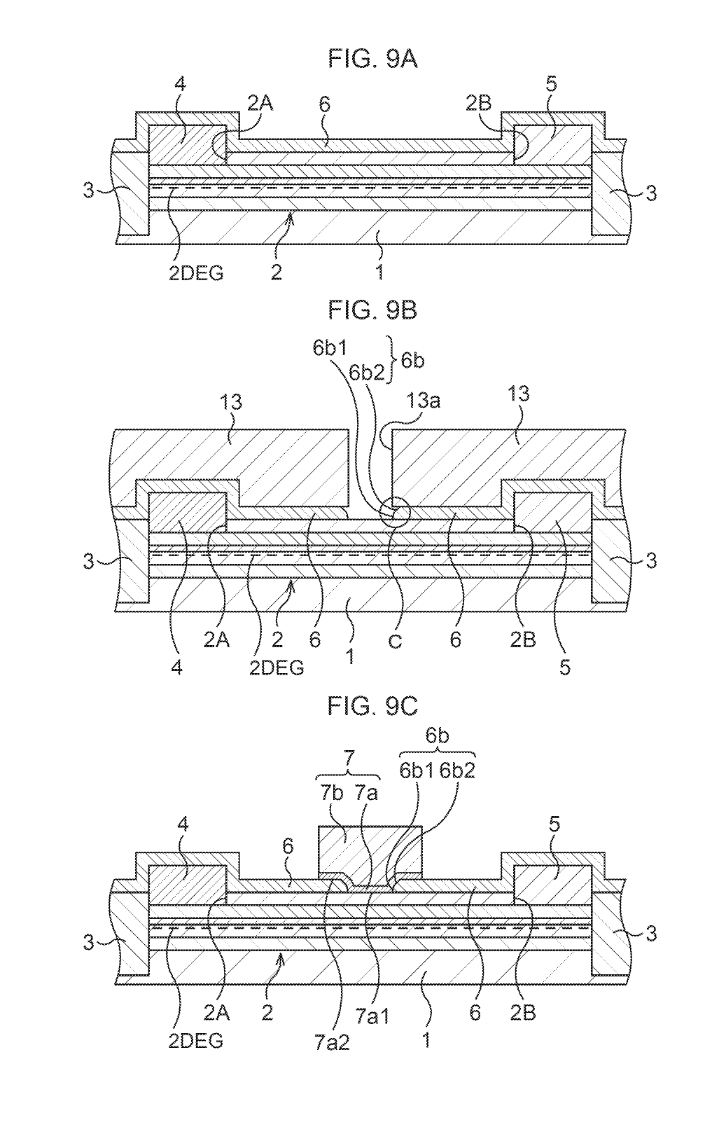

FIG. 9A to FIG. 9C are schematic cross-sectional diagrams illustrating main processes in a manufacturing method of the AlGaN/GaN HEMT according to the third embodiment.

First, through the processes in FIG. 1A to FIG. 2A of the first embodiment, a source electrode 4, a drain electrode 5, and a protective insulating film 6 are formed on a compound semiconductor layer 2. A state at this time is illustrated in FIG. 9A.

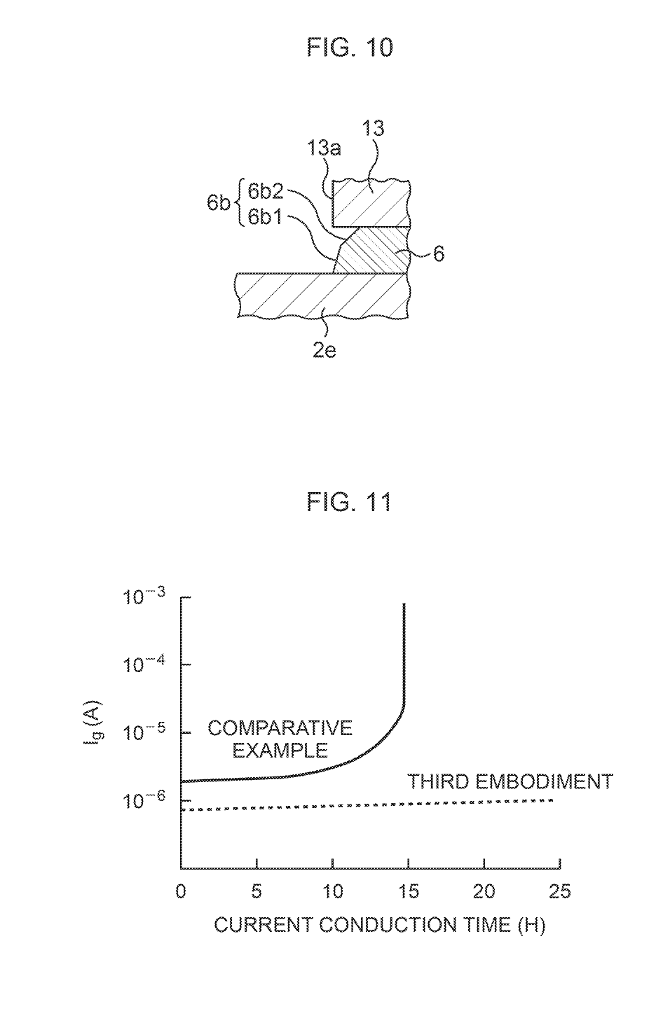

Subsequently, as illustrated in FIG. 9B and FIG. 10, a trench 6b is formed in the protective insulating film 6. FIG. 10 is a partial cross-sectional diagram illustrating a part within a circle C in FIG. 9B, in an enlarged manner.

Specifically, a resist is first applied on the whole surface of the protective insulating film 6. For example, PFI-32 (trade name) manufactured by Sumitomo Chemical Co., Ltd. is used as the resist. An ultraviolet method is used to perform, for example, exposure for an opening having a width of 600 nm on the applied resist, and the resist is developed. For example, NMD-W (trade name) manufactured by Tokyo Ohka Kogyo Co., Ltd. is used as a developing solution. Accordingly, a resist mask 13 having an opening 13a is formed.

Next, wet etching using the resist mask 13 is performed on the protective insulating film 6 until when a surface of a cap layer 2e is exposed at the bottom of the opening 13a. For example, buffered hydrofluoric acid is used as an etchant. Accordingly, the trench 6b that is a through trench exposing the surface of the cap layer 2e is formed in the protective insulating film 6. The trench 6b is formed such that its side wall surface is formed into an inclined surface by the wet etching, a width of a bottom portion is about 600 nm, and an upper portion is formed to be wider than the bottom portion. As illustrated in FIG. 10, in the trench 6b, the side wall surface is a two-stage forward tapered surface with different angles of inclination, in which a relatively steep first inclined surface 6b1 is first formed, and subsequently, a second inclined surface 6b2 whose inclination is gentler than that of the first inclined surface 6b1 (approximately about 45°) is formed.

The resist mask 13 is removed by ashing using oxygen plasma or wet treatment using a chemical solution.

Subsequently, a gate electrode 7 in which a Ni layer 7a and an Au layer 7b are stacked, is formed similar to the first embodiment, as illustrated in FIG. 9C. The gate electrode 7 has a so-called overhang shape, and is formed by having the Ni layer 7a which fills the trench 6b of the protective insulating film 6, which is in Schottky contact with the compound semiconductor layer 2 (cap layer 2e), and which rides on the protective insulating film 6, and the Au layer 7b on the Ni layer 7a. In the Ni layer 7a, a portion which is in Schottky contact with the compound semiconductor layer 2 (cap layer 2e) is set to a first contact portion 7a1, and a portion that is brought into contact with the protective insulating film 6 is set to a second contact portion 7a2. In the present embodiment, the protective insulating film 6 contains N—H bonds whose number exceeds 1×10²²/cm³, and is formed of SiN which is not oxidized. For this reason, an orientation state of the second contact portion 7a2 that is brought into contact with the protective insulating film 6 is set to the same orientation state as that of the first contact portion 7a1 which is in Schottky contact with the compound semiconductor layer 2 (cap layer 2e).

Thereafter, through processes of electrical connection of the source electrode 4, the drain electrode 5, and the gate electrode 7 and the like, the Schottky-type AlGaN/GaN HEMT is formed.

In the first embodiment, when a high drain voltage is applied to the AlGaN/GaN HEMT of the comparative example cited in FIG. 4, a high electric field is applied around the gate electrode 102. The high electric fields concentrate particularly on an electrode end of a Schottky contact portion of fine gate, and damage the compound semiconductor layer 100.

The gate electrode 102 is formed in the overhang shape with the stacked structure of the Ni layer 102a which fills the opening 101a of the protective insulating film 101, which is in Schottky contact with the surface of the compound semiconductor layer 100, and which rides on the protective insulating film 101, and the Au layer 102b on the Ni layer 102a. In this case, due to a step of the opening 101a of the protective insulating film 101, the Ni layer 102a may be cracked.

Further, as explained in the first embodiment, in the AlGaN/GaN HEMT of the comparative example, the orientation state of the Ni layer 102a becomes nonuniform. Specifically, the orientation state of the second contact portion 102a2 which is brought into contact with the protective insulating film 101 and the orientation state of the first contact portion 102a1 which is in Schottky contact with the compound semiconductor layer 100 are different.

A boundary portion of the mutually different orientations and the above-described crack occurred in the Ni layer 102a become a path through which Au is diffused on the compound semiconductor side from the Au layer 102b on the Ni layer 102a. This diffusion phenomenon is further accelerated due to the electric field concentration at the gate end described above, and the diffused Au conclusively reacts with the compound semiconductor, which causes a breakdown of device.

In the present embodiment, as illustrated in FIG. 9C, for example, the protective insulating film 6 with high hydrogen content in which it contains N—H bonds whose number exceeds 1×10²²/cm³, is formed. Hydrogen in the protective insulating film 6 improves the water repellency on the surface of the protective insulating film 6, and prevents the surface oxidation.

The protective insulating film 6 containing a large amount of hydrogen bonded to nitrogen, has very good adhesiveness with respect to a resist (novolac resist, for example). Therefore, it is possible to form the opening 6b in the protective insulating film 6 by the wet etching, as illustrated in FIG. 9B. Regarding the opening 6b, the side wall surface thereof is formed of the two-stage forward tapered surface with different angles of inclination, as described above. Accordingly, a steepness of the step of the opening is reduced, resulting in that the occurrence of crack in the Ni layer 7a is suppressed. It is of course that, since the protective insulating film 6 has a function of suppressing the surface oxidation, the formation of path through which Au is diffused, which is caused by the orientation abnormality of the Ni layer 7a, is prevented. Further, the two-stage forward tapered surface of the opening 6b alleviates the electric field concentration at the end portion of the gate electrode 7. By this configuration, the Au diffusion and the effect of accelerating the Au diffusion caused by the electric field are suppressed, resulting in that the breakdown of the gate electrode 7 and a peripheral structure of the gate electrode 7 is prevented.

A high-temperature current conduction test was carried out on the AlGaN/GaN HEMT according to the present embodiment, based on comparison with the comparative example cited in the first embodiment. The results are presented in FIG. 11.

It was confirmed that, in the present embodiment, the change in gate current (gate leakage current) in the high-temperature current conduction test was small and no breakdown occurred, unlike the comparative example. Namely, application of the protective insulating film 6 in the present embodiment realizes a highly reliable AlGaN/GaN HEMT with excellent output characteristics.

As described above, according to the present embodiment, it is possible to obtain a highly reliable AlGaN/GaN HEMT which suppresses a diffusion of gate electrode material and suppresses a breakdown of device by a relatively simple configuration to achieve high withstand voltage and high output power.

Further, there is realized an AlGaN/GaN HEMT with small change in device characteristics, capable of preventing a formation of path through which Au is diffused in the gate electrode 7, and alleviating the electric field concentration at the end portion of the gate electrode 7.

### Fourth Embodiment

The present embodiment discloses a power supply device including one kind of AlGaN/GaN HEMTs selected from the AlGaN/GaN HEMTs of the first to third embodiments.

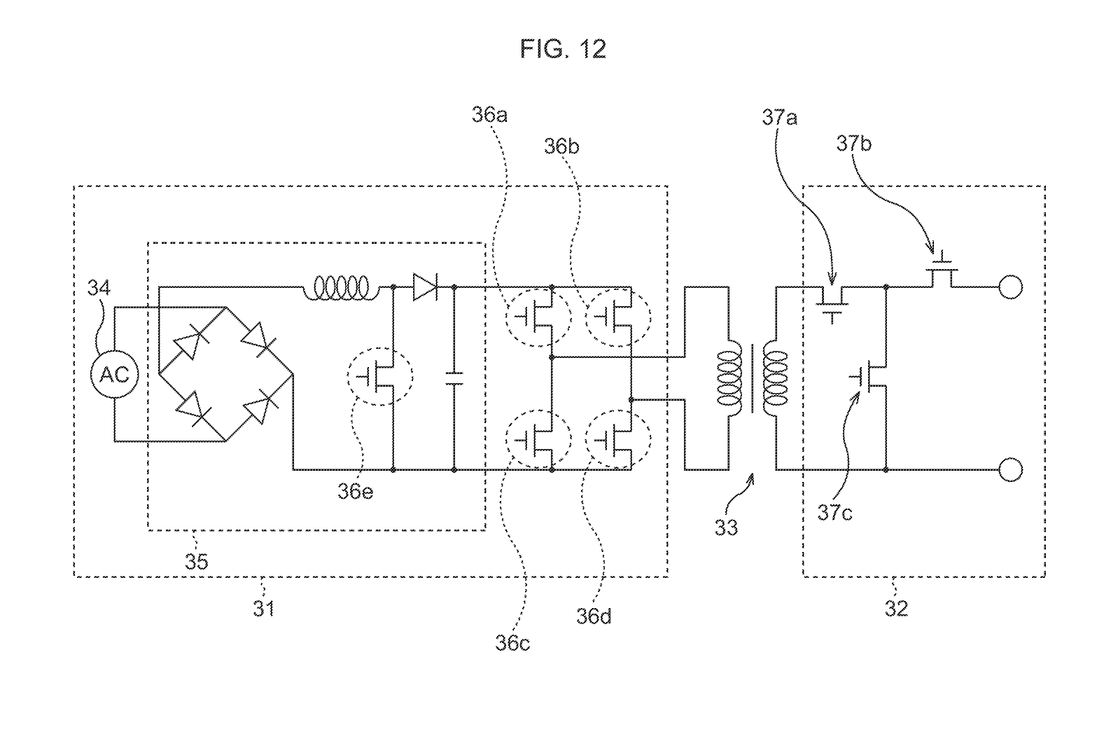

FIG. 12 is a connection diagram illustrating a schematic configuration of a power supply device according to a fourth embodiment.

The power supply device according to the present embodiment is configured by including a high-voltage primary-side circuit 31, a low-voltage secondary-side circuit 32, and a transformer 33 disposed between the primary-side circuit 31 and the secondary-side circuit 32.

The primary-side circuit 31 is configured by including an AC power supply 34, a so-called bridge rectifying circuit 35, and a plurality of (four, in this case) switching elements 36a, 36b, 36c, and 36d. Further, the bridge rectifying circuit 35 has a switching element 36e.

The secondary-side circuit 32 is configured by including a plurality of (three, in this case) switching elements 37a, 37b, and 37c.

In the present embodiment, each of the switching elements 36a, 36b, 36c, 36d, and 36e of the primary-side circuit 31 is set to one kind of the AlGaN/GaN HEMTs selected from the AlGaN/GaN HEMTs of the first to third embodiments. On the other hand, each of the switching elements 37a, 37b, and 37c of the secondary-side circuit 32 is set to an ordinary MIS•FET using silicon.

In the present embodiment, a highly reliable AlGaN/GaN HEMT which suppresses a diffusion of gate electrode material and suppresses a breakdown of device by a relatively simple configuration to achieve high withstand voltage and high output power, is applied to the high-voltage circuit. This realizes a highly reliable large-power power supply circuit.

### Fifth Embodiment

The present embodiment discloses a high-frequency amplifier including one kind of the AlGaN/GaN HEMTs selected from the AlGaN/GaN HEMTs of the first to third embodiments.

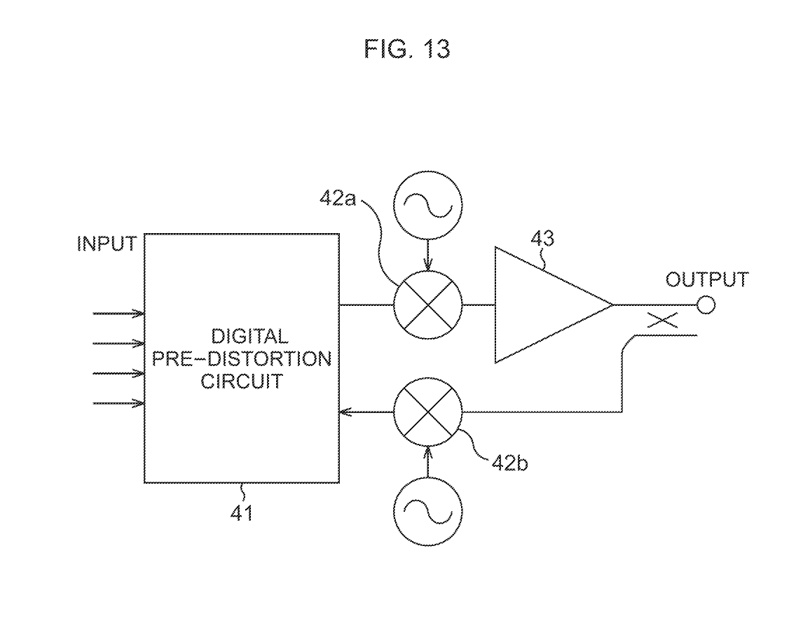

FIG. 13 is a connection diagram illustrating a schematic configuration of a high-frequency amplifier according to a fifth embodiment.

The high-frequency amplifier according to the present embodiment is configured by including a digital pre-distortion circuit 41, mixers 42a and 42b, and a power amplifier 43.

The digital pre-distortion circuit 41 compensates nonlinear distortion of an input signal. The mixer 42a mixes the input signal whose nonlinear distortion is compensated and an AC signal. The power amplifier 43 amplifies the input signal mixed with the AC signal, and has one kind of the AlGaN/GaN HEMTs selected from the AlGaN/GaN HEMTs of the first to third embodiments.

Note that in FIG. 13, it is configured such that by changing the switches, for example, an output-side signal can be mixed with the AC signal by the mixer 42b, and the resultant can be sent out to the digital pre-distortion circuit 41.

In the present embodiment, a highly reliable AlGaN/GaN HEMT which suppresses a diffusion of gate electrode material and suppresses a breakdown of device by a relatively simple configuration to achieve high withstand voltage and high output power, is applied to the high-frequency amplifier. This realizes a highly reliable high-withstand-voltage high-frequency amplifier.

### Other Embodiments

In the first to fifth embodiments, the AlGaN/GaN HEMTs are exemplified as the compound semiconductor devices. Other than the AlGaN/GaN HEMTs, the following HEMTs are applicable as the compound semiconductor devices.

Other HEMT Example 1

The present example discloses an InAlN/GaN HEMT as a compound semiconductor device.

InAlN and GaN are compound semiconductors whose lattice constants can be made to be close to each other by their compositions. In this case, in the above-described first to fifth embodiments, the electron transit layer is formed of i-GaN, the intermediate layer is formed of AlN, the electron supply layer is formed of n-InAlN, and the cap layer is formed of n-GaN. The n-GaN of the cap layer can be omitted as necessary. Further, since almost no piezoelectric polarization occurs in this case, two-dimensional electron gas is mainly generated by spontaneous polarization of InAlN.

According to the present example, a highly reliable InAlN/GaN HEMT which suppresses a diffusion of gate electrode material and suppresses a breakdown of device by a relatively simple configuration to achieve high withstand voltage and high output power, is realized, similar to the above-described AlGaN/GaN HEMTs.

Other HEMT Example 2

The present example discloses an InAlGaN/GaN HEMT as a compound semiconductor device.

GaN and InAlGaN are compound semiconductors in which the lattice constant of the latter is smaller than the lattice constant of the former. In this case, in the above-described first to fifth embodiments, the electron transit layer is formed of i-GaN, the intermediate layer is formed of i-InAlGaN, the electron supply layer is formed of n-InAlGaN, and the cap layer is formed of n⁺-GaN. The n⁺-GaN of the cap layer can be omitted as necessary.

According to the present example, a highly reliable InAlGaN/GaN HEMT which suppresses a diffusion of gate electrode material and suppresses a breakdown of device by a relatively simple configuration to achieve high withstand voltage and high output power, is realized, similar to the above-described AlGaN/GaN HEMTs.

According to the above-described aspects, it is possible to obtain a highly reliable compound semiconductor device which suppresses a diffusion of electrode material and suppresses a breakdown of device by a relatively simple configuration to achieve high withstand voltage and high output power.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device, comprising:
a compound semiconductor layer;
a protective insulating film that covers a top of the compound semiconductor layer and has an opening formed thereon; and
an electrode that fills the opening, that is brought into contact with the compound semiconductor layer, and that is formed on the protective insulating film, wherein
an orientation state of a contact portion between the electrode and the compound semiconductor layer and an orientation state of a contact portion between the electrode and the protective insulating film are the same.

2. The compound semiconductor device according to claim 1, wherein
the protective insulating film has a surface layer containing N—H bonds whose number exceeds 1.0×10²²/cm³.

3. The compound semiconductor device according to claim 1, wherein
the surface layer has a refractive index with respect to light with a wavelength of 633 nm of more than 1.9 and equal to or less than 2.0.

4. The compound semiconductor device according to claim 2, wherein
the protective insulating film is formed to have a stacked structure of a first insulating film being an arbitrary insulating film, and a second insulating film having the surface layer.

5. The compound semiconductor device according to claim 1, wherein
a side wall surface of the opening of the protective insulating film is formed into a two-stage forward tapered surface with different angles of inclination.

6. A manufacturing method of a compound semiconductor device, comprising:
forming a compound semiconductor layer;
forming a protective insulating film that covers a top of the compound semiconductor layer and has an opening; and
forming an electrode that fills the opening, that is brought into contact with the compound semiconductor layer, and that exists on the protective insulating film, wherein
an orientation state of a contact portion between the electrode and the compound semiconductor layer and an orientation state of a contact portion between the electrode and the protective insulating film are set to be the same.

7. The manufacturing method of the compound semiconductor device according to claim 6, wherein
the protective insulating film has a surface layer containing N—H bonds whose number exceeds 1.0×10²²/cm³.

8. The manufacturing method of the compound semiconductor device according to claim 6, wherein
the surface layer has a refractive index with respect to light with a wavelength of 633 nm of more than 1.9 and equal to or less than 2.0.

9. The manufacturing method of the compound semiconductor device according to claim 7, wherein
the protective insulating film is formed to have a stacked structure of a first insulating film being an arbitrary insulating film, and a second insulating film having the surface layer.

10. The manufacturing method of the compound semiconductor device according to claims 6, wherein
a side wall surface of the opening of the protective insulating film is formed into a two-stage forward tapered surface with different angles of inclination.

11. The manufacturing method of the compound semiconductor device according to claim 10, wherein
the side wall surface of the protective insulating film is formed into the forward tapered surface by wet etching.

12. A power supply circuit comprising a transformer, and a high-voltage circuit and a low-voltage circuit disposed by sandwiching the transformer,
the high-voltage circuit comprising a transistor,
the transistor comprising:
a compound semiconductor layer;
a protective insulating film that covers a top of the compound semiconductor layer and has an opening formed thereon; and
an electrode that fills the opening, that is brought into contact with the compound semiconductor layer, and that is formed on the protective insulating film, wherein
an orientation state of a contact portion between the electrode and the compound semiconductor layer and an orientation state of a contact portion between the electrode and the protective insulating film are the same.

13. A high-frequency amplifier that amplifies an input high-frequency voltage and outputs a resultant high-frequency voltage, the high-frequency amplifier comprising
a transistor,
the transistor comprising:
a compound semiconductor layer;
a protective insulating film that covers a top of the compound semiconductor layer and has an opening formed thereon; and
an electrode that fills the opening,
that is brought into contact with the compound semiconductor layer, and that is formed on the protective insulating film, wherein
an orientation state of a contact portion between the electrode and the compound semiconductor layer and an orientation state of a contact portion between the electrode and the protective insulating film are the same.
